(19) United States
(12) Patent Application Publication
(10) Pub. No.: US 2026/0065968 A1
(43) Pub. Date: Mar. 5, 2026

(54) MEMORY DEVICE AND OPERATING METHOD THEREOF

(71) Applicant: SAMSUNG ELECTRONICS CO., LTD., Suwon-si (KR)

(72) Inventors: Minsoo JANG, Suwon-si (KR); Manjae KIM, Suwon-si (KR); Yunsang CHO, Suwon-si (KR)

(73) Assignee: SAMSUNG ELECTRONICS CO., LTD., Suwon-si (KR)

(21) Appl. No.: 19/264,158

(22) Filed: Jul. 9, 2025

(30) Foreign Application Priority Data
Sep. 5, 2024 (KR) 10-2024-0120950

(51) Int. Cl. G11C 11/406

(52) U.S. Cl. CPC G11C 11/40622; G11C 11/40615; G11C 11/40626

(57) ABSTRACT

A memory device includes a memory cell array including normal cells and per row activation count (PRAC) cells coupled with a plurality of word lines corresponding to a plurality of rows, a refresh control circuit configured to refresh the plurality of word lines corresponding to the plurality of rows based on a refresh command, and an activation generating circuit configured to generate a row activation signal based on an activation command. The row activation signal is configured to activate the plurality of word lines corresponding to a row address of the plurality of rows. Each of the PRAC cells is configured to store row activation information. Each of the normal cells is configured to store data.

### CROSS-REFERENCE TO RELATED APPLICATION

This application claims benefit of priority under 35 U.S.C. § 119 to Korean Patent Application No. 10-2024-0120950, filed on Sep. 5, 2024, in the Korean Intellectual Property Office, the disclosure of which is incorporated by reference herein in its entirety.

### BACKGROUND

### 1. Field

The present disclosure relates generally to a semiconductor memory device, and more particularly, to a memory device performing a refresh operation and an operating method of the memory device.

### 2. Description of Related Art

A dynamic random access memory (DRAM) may refer to a representative semiconductor memory device that may need to perform a periodic refresh operation for retaining data stored in a memory cell. A refresh operation may include, but not be limited to, an auto refresh operation and a self-refresh operation. In a case where DRAM is used in mobile application products (e.g., smartphones, mobile phones, personal digital assistants (PDAs), tablet computers, laptop computers, personal computers (PCs), wearable devices, smart appliances, healthcare devices, Internet of Things (IoT) devices, or the like), relatively low power consumption may be desirable. Thus, there exists a need for further improvements in semiconductor memory devices, as the need for low power consumption may be constrained by a need to perform periodic refresh operations to retain data stored therein. For example, performing a partial array self-refresh operation may result in a lower power consumption compared to related refresh operations.

### SUMMARY

One or more example embodiments of the present disclosure provide a memory device and an operating method thereof, which may determine whether a word line is activated in a self-refresh operation and may selectively perform a refresh operation on the word line, based on whether the word line is activated.

According to an aspect of the present disclosure, a memory device includes a memory cell array including normal cells and per row activation count (PRAC) cells coupled with a plurality of word lines corresponding to a plurality of rows, a refresh control circuit configured to refresh the plurality of word lines corresponding to the plurality of rows based on a refresh command, and an activation generating circuit configured to generate a row activation signal based on an activation command. The row activation signal is configured to activate the plurality of word lines corresponding to a row address of the plurality of rows. Each of the PRAC cells is configured to store row activation information. Each of the normal cells is configured to store data.

According to an aspect of the present disclosure, a memory device includes a row decoder configured to activate an n-th row corresponding to an n-th row address and an (n+1)-th row corresponding to an (n+1)-th row address, a memory cell array including an n-th PRAC cell and n-th normal cells coupled with an n-th word line corresponding to the n-th row and an (n+1)-th PRAC cell and (n+1)-th normal cells coupled with an (n+1)-th word line corresponding to the (n+1)-th row, an activation generating circuit configured to generate a row activation signal based on an activation command, a mask control circuit configured to scan whether at least one of the n-th word line or the (n+1)-th word line is activated, and determine to selectively perform a refresh operation on the at least one of the n-th word line or the (n+1)-th word line that is activated, and a refresh control circuit configured to perform, based on a refresh command, the refresh operation on at least one of the n-th word line or the (n+1)-th word line. The row activation information is stored in at least one PRAC cell coupled with the at least one of the n-th word line or the (n+1)-th word line that is activated. n is a positive integer greater than zero (0).

According to an aspect of the present disclosure, an operating method of a memory device includes receiving an activation command, generating a row activation signal, activating, based on the row activation signal, an n-th word line corresponding to an n-th row and stopping activation of an (n+1)-th word line corresponding to an (n+1)-th row, storing a bit value of one (1) in an n-th per row activation count PRAC cell coupled with the n-th word line, storing a bit value of zero (0) in an (n+1)-th PRAC cell coupled with the (n+1)-th word line, and storing a bit value of zero (0) in an (n+2)-th PRAC cell coupled with an (n+2)-th word line. n is a positive integer greater than zero (0).

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a block diagram illustrating a memory system, according to an embodiment;

FIG. 2 is a block diagram illustrating a memory device, according to an embodiment;

FIG. 3 is a block diagram illustrating a refresh control circuit, according to an embodiment;

FIG. 4 is a block diagram illustrating a mask control circuit, according to an embodiment;

FIG. 5 is a timing diagram illustrating a self-refresh period, according to an embodiment;

FIG. 6 is a block diagram illustrating a memory device, according to an embodiment;

FIG. 7 is a flowchart illustrating an operating method of a memory device, according to an embodiment;

FIG. 8 is a block diagram illustrating a memory device, according to an embodiment;

FIG. 9 is a block diagram illustrating a memory device, according to an embodiment;

FIG. 10 is a block diagram illustrating a memory system, according to an embodiment;

FIG. 11 is a block diagram illustrating a computing system including a memory system, according to an embodiment; and

FIG. 12 is a block diagram illustrating a system for describing an electronic device including a memory device, according to an embodiment.

### DETAILED DESCRIPTION OF THE EMBODIMENTS

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as, but not limited to device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

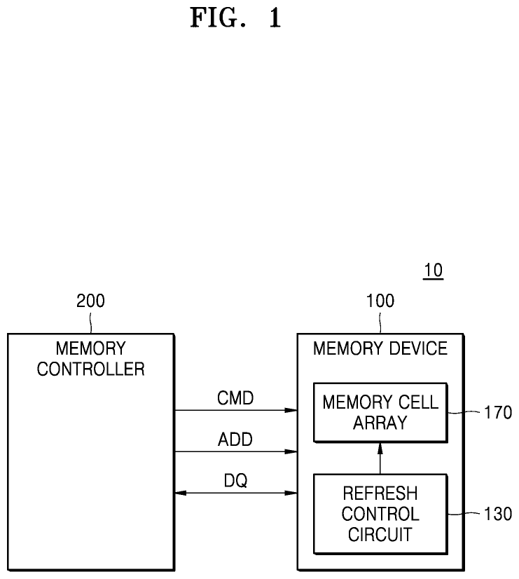

FIG. 1 is a block diagram illustrating a memory system 10, according to an embodiment.

Referring to FIG. 1, the memory system 10 may include a memory controller 200 and a memory device 100, and the memory device 100 may include a memory cell array 170 and a refresh control circuit 130.

The memory system 10 may be coupled to a host and may be accessed by the host. The memory system 10 may be and/or may include a functional block that may perform a general computer operation of an electronic device and may correspond to a central processing unit (CPU), a digital signal processor (DSP), a graphics processing unit (GPU), or an application processor (AP).

The memory controller 200 may control overall an operation of the memory system 10 and may control overall data exchange between an external host and the memory device 100. For example, the memory controller 200 may control the memory device 100 to write data and/or read data, based on a request of the host. In addition, the memory controller 200 may apply an operation command for controlling the memory device 100 to control an operation of the memory device 100.

The memory controller 200 may provide a command CMD and/or an address ADD to the memory device 100 to write data DQ in the memory device 100 and/or read the data DQ from the memory device 100. In addition, the memory controller 200 may transfer and/or receive the data DQ to and/or from the memory device 100. For example, the memory controller 200 and the memory device 100 may exchange the command CMD, the address ADD, and/or the data DQ therebetween by using an individual pin and/or channel.

The memory device 100 may be and/or may include dynamic random access memory (DRAM) such as, but not limited to, double data rate synchronous DRAM (DDR SDRAM), low power double data rate (LPDDR) SDRAM, graphics double data rate (GDDR) SDRAM, Rambus dynamic random access memory (RDRAM), or the like.

The memory device 100, according to an embodiment, may request a periodic refresh operation so as to retain data stored in the memory cell array 170. A refresh operation may include, but not be limited to, an auto refresh operation and a self-refresh operation. The auto refresh operation may be performed by a refresh command input from the memory controller 200, and the self-refresh operation may be performed by a refresh signal which may be periodically and/or automatically generated in the memory device 100.

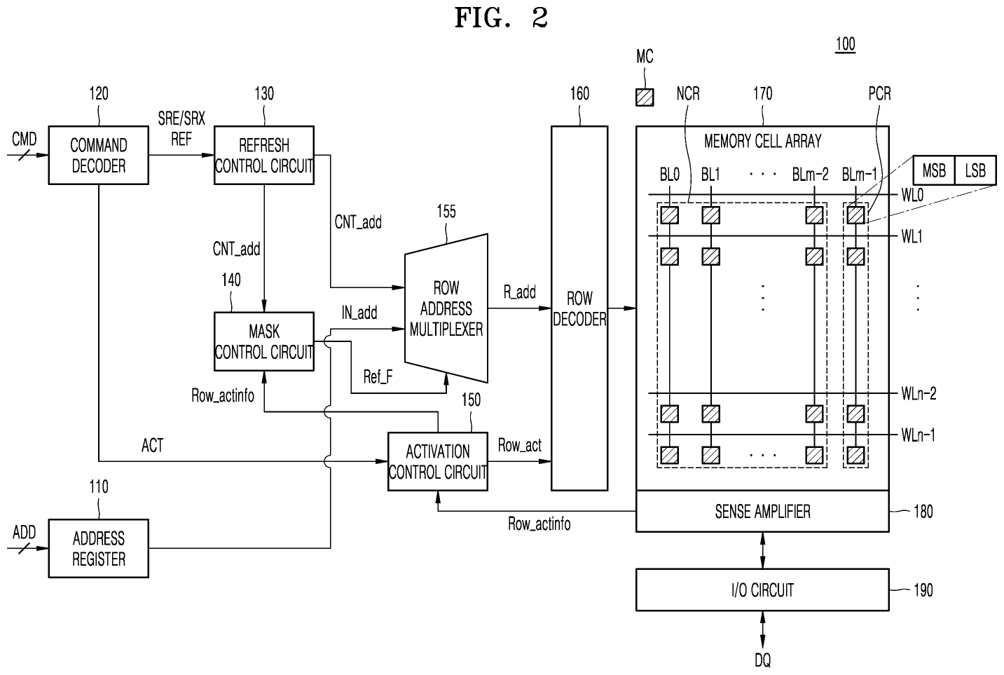

The memory cell array 170, according to an embodiment, may include a plurality of memory cells. The plurality of memory cells may include normal cells and per row activation count (PRAC) cells. The normal cells may store data. The PRAC cells may include x bits, where x is a positive integer greater than zero (0). For example, the PRAC cells may include two (2) bits (e.g., x=2). However, the present disclosure is not limited thereto. The PRAC cells may store row activation information and refresh information. For example, the PRAC cells may store row activation information and refresh information related to a plurality of word lines corresponding to a plurality of rows. A configuration of the PRAC cell of the memory cell array 170 is described with reference to FIG. 2.

The refresh control circuit 130 may autonomously perform a self-refresh operation in the memory device 100. For example, the self-refresh operation may be performed at a standby time so as to satisfy a low power consumption design constraint. Alternatively or additionally, the refresh control circuit 130 may perform a partial array self-refresh (PSR) operation, and the PSR operation may be performed in only a certain region of the memory cell array 170 instead of being performed on the memory cell array 170 as a whole. That is, the refresh control circuit 130 may perform a self-refresh operation by word line units. However, the present disclosure is not limited in this regard, and the self-refresh operation may be performed based on other units and/or groupings without departing from the scope of the present disclosure.

Power consumption of the memory device 100 may increase unnecessarily due to performing a refresh operation for securing a retainment time that may be different from an active operation of the memory device 100 such as, but not limited to, a read operation, a write operation, a precharge operation, or the like.

However, for example, when a PSR operation is performed in the memory device 100, the power consumption of the memory device 100 for a standby time may be reduced, in comparison, as the performing of a refresh operation on a region of the memory device 100, in which data retainment may not be needed, may be omitted.

FIG. 2 is a block diagram illustrating a memory device 100, according to an embodiment. The memory device 100 of FIG. 2 may include and/or may be similar in many respects to the memory device 100 described above with reference to FIG. 1, and may include additional features not mentioned above. Furthermore, a refresh control circuit 130 and a memory cell array 170 of FIG. 2 may include and/or may be similar in many respects to the refresh control circuit 130 and the memory cell array 170 described above with reference to FIG. 1, respectively, and may include additional features not mentioned above. Consequently, repeated descriptions of the memory device 100 described above with reference to FIG. 1 may be omitted for the sake of brevity.

Referring to FIG. 2, the memory device 100 may include an address register 110, a command decoder 120, the refresh control circuit 130, a mask control circuit 140, an activation control circuit 150, a row address multiplexer 155, a row decoder 160, the memory cell array 170 including a plurality of memory cells MC, a sense amplifier 180, and an input/output (I/O) circuit 190.

Referring to FIGS. 1 and 2, the command decoder 120 may decode a command CMD received from the memory controller 200 to output a self-refresh entry signal SRE and/or a self-refresh exit signal SRX to the refresh control circuit 130. For example, the command decoder 120 may decode the self-refresh entry signal SRE to output to the refresh control circuit 130 and/or may decode the self-refresh exit signal SRX to output to the refresh control circuit 130.

The command decoder 120 may decode the command CMD input from the memory controller 200 to generate an activation command ACT and a refresh command REF each associated with a row access operation. Moreover, the command decoder 120 may generate an internal command such as, but not limited to, a write command, a read command, or a precharge command associated with a data I/O operation.

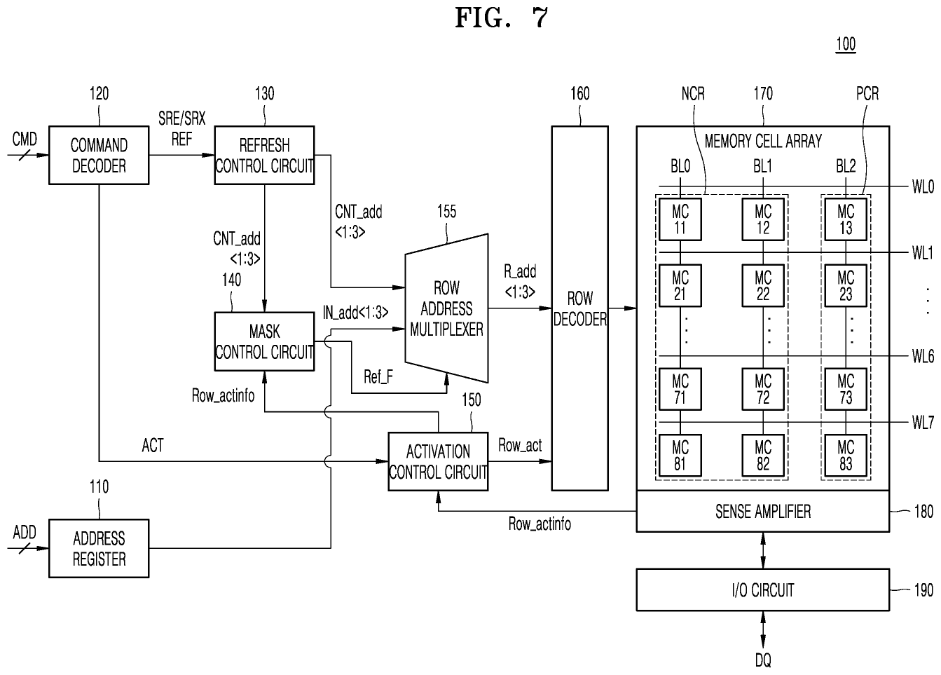

The address register 110 may receive an address ADD from the memory controller 200. The address register 110 may provide an input address IN_add to the row address multiplexer 155. The input address IN_add may be classified into a row address for designating a plurality of word lines (e.g., a first word line WL0, a second word line WL1, to an (n−1)-th word line WLn−2, and an n-th word line WLn−1, where n is a positive integer greater than one (1)), and a column address for designating bit lines. Hereinafter, in an embodiment, an example where the input address IN_add is configured with a three-bit (3-bit) row address for designating each of a plurality of first to eighth word lines WL0 to WL7 (e.g., n=8) is described with reference to FIG. 7.

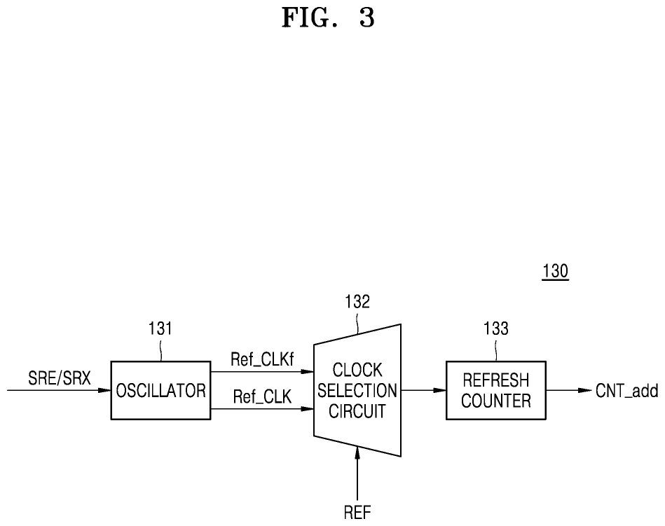

The refresh control circuit 130 may generate a counting address CNT_add in response to the self-refresh entry signal SRE. The refresh control circuit 130 may be enabled in response to the self-refresh entry signal SRE and may be disabled in response to the self-refresh exit signal SRX. The refresh control circuit 130 may provide the counting address CNT_add to the mask control circuit 140. A configuration of the refresh control circuit 130 and a method of generating the counting address CNT_add are described with reference to FIG. 3.

The activation control circuit 150 may generate a row activation signal Row_act, based on the activation command ACT received from the command decoder 120. The activation control circuit 150 may be activated based on the activation command ACT. The activation control circuit 150 may provide the row activation signal Row_act to the row decoder 160. As used herein, the row activation signal Row_act may refer to a signal that may activate at least one word line of the plurality of first to n-th word lines WL0 to WLn−1 corresponding to an input address IN_add.

The activation control circuit 150 may receive row activation information Row_actinfo from the sense amplifier 180. The row activation information Row_actinfo may be and/or may include information about the at least one word line of the plurality of first to n-th word lines WL0 to WLn−1 activated based on the row activation signal Row_act. The activation control circuit 150 may provide the row activation information Row_actinfo to the mask control circuit 140.

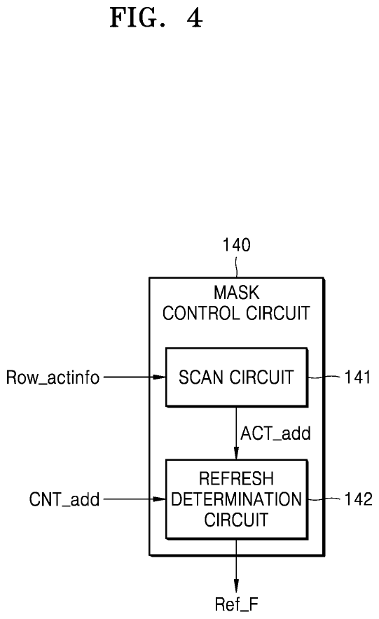

The mask control circuit 140 may receive the counting address CNT_add and the row activation information Row_actinfo. The mask control circuit 140 may receive the row activation information Row_actinfo to scan whether at least one word line of the plurality of first to n-th word lines WL0 to WLn−1 connected to the memory cell array 170 is activated. The mask control circuit 140 may determine whether to perform a self-refresh operation of the plurality of first to n-th word lines WL0 to WLn−1 of the memory cell array 170 by using the counting address CNT_add and the row activation information Row_actinfo. The mask control circuit 140 may generate a final refresh command REF_F by using the counting address CNT_add and the row activation information Row_actinfo. The mask control circuit 140 may provide the final refresh command REF_F to the row address multiplexer 155. A configuration of the mask control circuit 140 and a method of generating the final refresh command REF_F are described with reference to FIG. 4.

The row address multiplexer 155 may select at least one of the counting address CNT_add or the input address IN_add to output as a row address R_add, based on the final refresh command REF_F. For example, the row address multiplexer 155 may output the input address IN_add as the row address R_add. Alternatively or additionally, when the final refresh command REF_F is input, the row address multiplexer 155 may select the counting address CNT_add to output the row address R_add.

In an embodiment, the row decoder 160 may select at least one word line of the plurality of first to n-th word lines WL0 to WLn−1 in response to a row selection signal. In addition, the row decoder 160 may activate at least one word line of the plurality of first to n-th word lines WL0 to WLn−1 corresponding to the row address R_add, based on the row activation signal Row_act. The row decoder 160 may decode the row address R_add output from the row address multiplexer 155 to activate a word line corresponding to the row address R_add. For example, the activated row decoder 160 may apply a word line driving voltage to the word line corresponding to the row address R_add.

The memory cell array 170 may include a plurality of memory cells MC. The plurality of memory cells MC may include normal cells and PRAC cells. In an embodiment, the memory cell array 170 may include a normal cell region NCR and a PRAC cell region PCR. For example, the normal cell region NCR may include normal cells, and the PRAC cell region PCR may include PRAC cells. In the memory cell array 170, the plurality of first to n-th word lines WL0 to WLn−1 and a plurality of bit lines (e.g., a first bit line BL0, a second bit line BL1, to an (m−1)-th bit line BLm−2, and an m-th bit line BLm−1, where m is a positive integer greater than one (1), and m may be different from and/or equal to n) may intersect with one another, and normal cells and PRAC cells may be arranged at intersection points between the plurality of first to n-th word lines WL0 to WLn−1 and the plurality of first to m-th bit lines BL0 to BLm−1. The row decoder 160 may be configured to select at least one of the plurality of first to n-th word lines WL0 to WLn−1 included in the memory cell array 170. Each memory cell of the plurality of memory cells MC may be and/or may include, for example, a DRAM cell. However, the present disclosure is not limited in this regard.

The plurality of memory cells MC may store a plurality of bits. For example, the normal cells of the normal cell region NCR may store data configured with a plurality of bits. The normal cells may be respectively connected to a plurality of word lines corresponding to a plurality of rows and may store data. For example, each of the PRAC cells of the PRAC cell region PCR may include x bits, where x is a positive integer greater than zero (0). For example, the PRAC cells may include two (2) bits (e.g., x=2). However, the present disclosure is not limited thereto. The PRAC cells may store row activation information and refresh information. Each of the PRAC cells may store row activation information and refresh information related to a plurality of word lines corresponding to a plurality of rows. For example, the row activation information Row_actinfo representing whether a word line is activated may be stored at a most significant bit (MSB) of two (2) bits of the PRAC cell, and self-refresh operation information representing whether to perform a self-refresh operation of the word line may be stored at a least significant bit (LSB). However, the present disclosure is not limited thereto.

According to an embodiment, when the row activation signal Row_act is applied to the row decoder 160, the PRAC cells of the PRAC cell region PCR may store the activated word lines of the plurality of first to n-th word lines WL0 to WLn−1 as the row activation information Row_actinfo. For example, a bit value of one (1) (e.g., high) may be stored in PRAC cells connected to activated word lines, and a bit value of zero (0) (e.g., low) may be stored in PRAC cells connected to deactivated word lines.

For example, when an n-th word line WLn−1 is activated, a bit value of one (1) may be stored in PRAC cells connected to the n-th word line WLn−1, and when the n-th word line WLn−1 is not activated, a bit value of zero (0) may be stored in the PRAC cells connected to the n-th word line WLn−1. As another example, when a first word line WL0 is activated, a bit value of one (1) may be stored in PRAC cells connected to the first word line WL0. When a second word line WL1 is not activated, a bit value of zero (0) may be stored in PRAC cells connected to the second word line WL1.

In an embodiment, when the n-th word line WLn−1 is activated, the row activation information Row_actinfo may be stored as a bit value of one (1) at an MSB of a PRAC cell connected to the n-th word line WLn−1, and when the n-th word line WLn−1 is not activated, the row activation information Row_actinfo may be stored as a bit value of zero (0) at the MSB of the PRAC cell connected to the n-th word line WLn−1.

According to an embodiment, when the final refresh command REF_F is applied to the row decoder 160, the PRAC cells of the PRAC cell region PCR may store self-refresh information representing whether a self-refresh operation on at least one word line of the plurality of first to n-th word lines WL0 to WLn−1 is needed, based on whether the at least one word line is activated. For example, a bit value of one (1) may be stored in a PRAC cell connected to a word line subsequent to a word line which needs a self-refresh operation, and a bit value of zero (0) may be stored in a PRAC cell connected to a word line subsequent to a word line which does not need a self-refresh operation.

For example, when a self-refresh operation on an (n−1)-th word line WLn−2 is needed, a bit value of one (1) may be stored in a PRAC cell connected to the n-th word line WLn−1 subsequent to the (n−1)-th word line WLn−2, and when a self-refresh operation on the (n−1)-th word line WLn−2 is omitted (e.g., not needed), a bit value of zero (0) may be stored in a PRAC cell connected to the n-th word line WLn−1 subsequent to the (n−1)-th word line WLn−2. As another example, when the first word line WL0 is activated and thus a self-refresh operation is needed, a bit value of one (1) may be stored in a PRAC cell connected to the second word line WL1 subsequent to the first word line WL0 instead of a PRAC cell connected to the first word line WL0. When the second word line WL1 is not activated and thus a self-refresh operation may be omitted, a bit value of zero (0) may be stored in a PRAC cell connected to the third word line WL2 subsequent to the second word line WL1 instead of a PRAC cell connected to the second word line WL1.

In an embodiment, when a self-refresh operation on an (n−1)-th word line WLn−2 is needed, a bit value of one (1) may be stored at an LSB of a PRAC cell connected to the n-th word line WLn−1 subsequent to the (n−1)-th word line WLn−2, and when a self-refresh operation on the (n−1)-th word line WLn−2 may be omitted, a bit value of zero (0) may be stored at an LSB of a PRAC cell connected to the n-th word line WLn−1 subsequent to the (n−1)-th word line WLn−2.

That is, according to an embodiment, in a case where information about a word line requiring a self-refresh operation is stored in a PRAC cell, the information about the word line may be stored in a subsequent PRAC cell succeeding a next word line.

For example, the row activation information Row_actinfo representing whether a word line is activated may be stored at an MSB of a plurality of bits of a PRAC cell, and self-refresh operation information representing whether to perform a self-refresh operation of the word line may be stored at an LSB. However, the present disclosure is not limited thereto.

The sense amplifier 180 may be connected to the memory cell array 170. The data DQ read from the PRAC cell region PCR of the memory cell array 170 may be sensed by the sense amplifier 180. The sense amplifier 180 may write data in a memory cell selected by a selected bit line, or may sense written data. The sense amplifier 180 may sense and output data, stored in PRAC cells, through an m-th bit line BLm−1. The sense amplifier 180 may output row activation information about word lines activated by the activation control circuit 150. That is, the sense amplifier 180 may amplify and output data of memory cells connected to the activated word lines.

The I/O circuit 190 may provide the read data DQ to the outside (e.g., a memory controller). In addition, the data DQ which is to be written in the normal cell region NCR or the PRAC cell region PCR included in each memory cell of the plurality of memory cells MC of the memory cell array 170 may be provided from the memory controller to the I/O circuit 190. The data DQ provided to the I/O circuit 190 may be written in the memory cell array 170 through write drivers.

In an embodiment, the above-described components of the memory device 100 (e.g., the address register 110, the command decoder 120, the refresh control circuit 130, the mask control circuit 140, the activation control circuit 150, the row address multiplexer 155, the row decoder 160, the memory cell array 170 including the plurality of memory cells MC, the sense amplifier 180, and the I/O circuit 190) may be physically implemented by analog and/or digital circuits including one or more of a logic gate, an integrated circuit, a microprocessor, a microcontroller, a memory circuit, a passive electronic component, an active electronic component, an optical component, and the like. For example, a field programmable gate array (FPGA) may be used to implement custom logic that may include the functionality of the above-described components of the memory device 100. As another example, a processor in combination with a memory may be used to execute one or more instructions to perform the functionality of the memory device 100. Alternatively or additionally, at least a portion of the functionality of the memory device 100 may be incorporated into the memory controller 200 and/or implemented as instructions to be executed by the memory controller 200.

The number and arrangement of components of the memory device 100 shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Alternatively or additionally, a set of (one or more) components shown in FIG. 2 may be integrated with each other, and/or may be implemented as an integrated circuit, as software, and/or a combination of circuits and software.

The memory device 100, according to an embodiment, may omit a refresh operation of a word line where an active operation is not performed, and thus, may minimize power consumption in the refresh operation, when compared to a related memory device.

According to an embodiment, the memory device 100 may store activation information about the plurality of first to n-th word lines WL0 to WLn−1 corresponding to the row address R_add in the PRAC cells of the plurality of memory cells MC. For example, the memory device 100 may determine whether at least one word line of the plurality of first to n-th word lines WL0 to WLn−1 corresponding to the row address R_add is activated, and based thereon, the memory device 100 may not perform a self-refresh operation on word lines corresponding to a row address which is not activated and may perform a self-refresh operation on only word lines corresponding to activated row addresses.

That is, the memory device 100 may determine whether word lines corresponding to row addresses of PRAC cells are activated, and based thereon, the memory device 100 may perform a self-refresh operation on only memory cells connected to word lines corresponding to an activated row address and may omit a self-refresh operation on memory cells connected to word lines corresponding to a deactivated row address.

FIG. 3 is a block diagram illustrating a refresh control circuit 130, according to an embodiment. The refresh control circuit 130 of FIG. 3 may include and/or may be similar in many respects to the refresh control circuit 130 described above with reference to FIGS. 1 and 2, and may include additional features not mentioned above. Consequently, repeated descriptions of the refresh control circuit 130 described above with reference to FIGS. 1 and 2 may be omitted for the sake of brevity.

Referring to FIG. 3, the refresh control circuit 130 may include an oscillator 131, a clock selection circuit 132, and a refresh counter 133.

The oscillator 131 may be activated in response to the self-refresh entry signal SRE received from the command decoder 120 and may be deactivated in response to the self-refresh exit signal SRX. The oscillator 131 may be activated when the memory device 100 performs a self-refresh operation. Alternatively or additionally, the oscillator 131 may be deactivated when the memory device 100 stops the self-refresh operation.

The oscillator 131 may adjust a frequency of a refresh clock and output at least one refresh clock signal based on the adjusted frequency. The oscillator 131 may output a first refresh clock Ref_CLKf and a second refresh clock Ref_CLK. For example, the oscillator 131 may adjust a frequency of the second refresh clock Ref_CLK to output the first refresh clock Ref_CLKf. A frequency of the first refresh clock Ref_CLKf may be the same as a frequency which may be obtained by multiplying a frequency of the second refresh clock Ref_CLK by a factor f, where f is a real number.

The clock selection circuit 132 may receive the first refresh clock Ref_CLKf and the second refresh clock Ref_CLK and may receive the self-refresh command REF from the command decoder 120. The clock selection circuit 132 may select and output the first refresh clock Ref_CLKf so as to determine whether at least one word line of the plurality of first to n-th word lines WL0 to WLn−1 is activated. An operation of selecting the first refresh clock Ref_CLKf by using the clock selection circuit 132 to determine whether at least one word line of the plurality of first to n-th word lines WL0 to WLn−1 is activated may be referred to as a first self-refresh operation, and a first self-refresh operation period may be referred to as a first self-refresh cycle. The clock selection circuit 132 may select and output the second refresh clock Ref_CLK so as to perform a self-refresh operation of the plurality of first to n-th word lines WL0 to WLn−1. An operation of selecting the second refresh clock Ref_CLK by using the clock selection circuit 132 to perform a self-refresh operation on only a word line requiring the self-refresh operation among the plurality of first to n-th word lines WL0 to WLn−1, and may be referred to as a second self-refresh operation, and a second self-refresh operation period may be referred to as a second self-refresh cycle.

The refresh counter 133 may perform a counting operation of an input address in response to the first refresh clock Ref_CLKf or the second refresh clock Ref_CLK. For example, the counting operation may refer to an operation of increasing a bit of the input address by one (1). The refresh counter 133 may generate a count address CNT_add that may sequentially increase based on the self-refresh command REF. The refresh counter 133 may increase a counting address by one (1) whenever the self-refresh command REF is input and may output an increased counting address. The refresh counter 133 may provide the row address multiplexer 155 with the counting address CNT_add on which a counting operation has been performed.

FIG. 4 is a block diagram illustrating a mask control circuit 140, according to an embodiment. The mask control circuit 140 of FIG. 4 may include and/or may be similar in many respects to the mask control circuit 140 described above with reference to FIG. 2, and may include additional features not mentioned above. Consequently, repeated descriptions of the mask control circuit 140 described above with reference to FIG. 2 may be omitted for the sake of brevity.

Referring to FIG. 4, the mask control circuit 140 may include a scan circuit 141 and a refresh determination circuit 142.

Referring to FIGS. 2 and 4, the scan circuit 141 may receive row activation information Row_actinfo. The row activation information Row_actinfo may be and/or may include activation information about the plurality of first to n-th word lines WL0 to WLn−1 stored in PRAC cells included in the memory cell array 170. The row activation information Row_actinfo may be stored as a bit value of one (1) or zero (0) in the PRAC cells. The scan circuit 141 may scan and/or determine whether at least one word line of the plurality of first to n-th word lines WL0 to WLn−1 corresponding to a plurality of rows is activated, based on the row activation information Row_actinfo. The scan circuit 141 may output an active address ACT_Add of activated word lines.

The refresh determination circuit 142 may receive the active address ACT_Add output from the scan circuit 141 and the counting address CNT_add output from the refresh control circuit 130. The refresh determination circuit 142 may determine whether to perform a self-refresh operation of an activated word line, based on the active address ACT_Add and the counting address CNT_add. For example, the refresh determination circuit 142 may determine to perform the self-refresh operation of the activated word line and may determine to omit a self-refresh operation of a deactivated word line. That is, the refresh determination circuit 142 may determine to selectively perform a self-refresh operation on the plurality of first to n-th word lines WL0 to WLn−1. The refresh determination circuit 142 may output a final refresh command REF_F. The refresh determination circuit 142 may provide the final refresh command REF_F to the row address multiplexer 155.

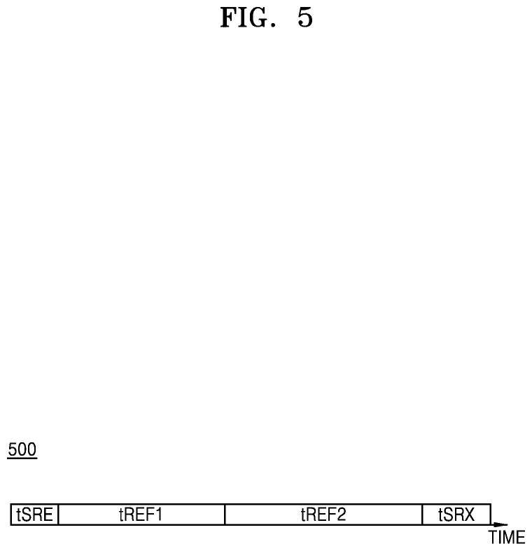

FIG. 5 is a timing diagram 500 illustrating a self-refresh period, according to an embodiment.

Referring to FIGS. 2 and 5, the memory device 100, according to an embodiment, may receive the self-refresh entry signal SRE to perform a self-refresh operation. A period during which the self-refresh entry signal SRE is received may be referred to as a self-refresh entry period tSRE.

Referring to FIGS. 3 and 5, the memory device 100, according to an embodiment, may scan whether at least one word line of the plurality of first to n-th word lines WL0 to WLn−1 is activated in the mask control circuit 140, based on the first refresh clock signal Ref_CLKf, may determine to perform a self-refresh operation on the activated word lines, and may determine to omit a self-refresh operation on deactivated word lines. A period during which it is determined whether at least one word line of the plurality of first to n-th word lines WL0 to WLn−1 is activated by using the first refresh clock signal Ref_CLKf and a self-refresh operation is determined and stored may be referred to as a first refresh cycle period tREF1.

Referring to FIGS. 3 and 5, a period during which the memory device 100, according to an embodiment, performs a self-refresh operation on activated word lines by using the second refresh clock signal Ref_CLK and omits a self-refresh operation on deactivated word lines may be referred to as a second refresh cycle period tREF2.

Referring to FIGS. 2 and 5, the memory device 100, according to an embodiment, may receive the self-refresh exit signal SRX to end a self-refresh operation. A period where the self-refresh exit signal SRX is received may be referred to as a self-refresh exit period tSRX.

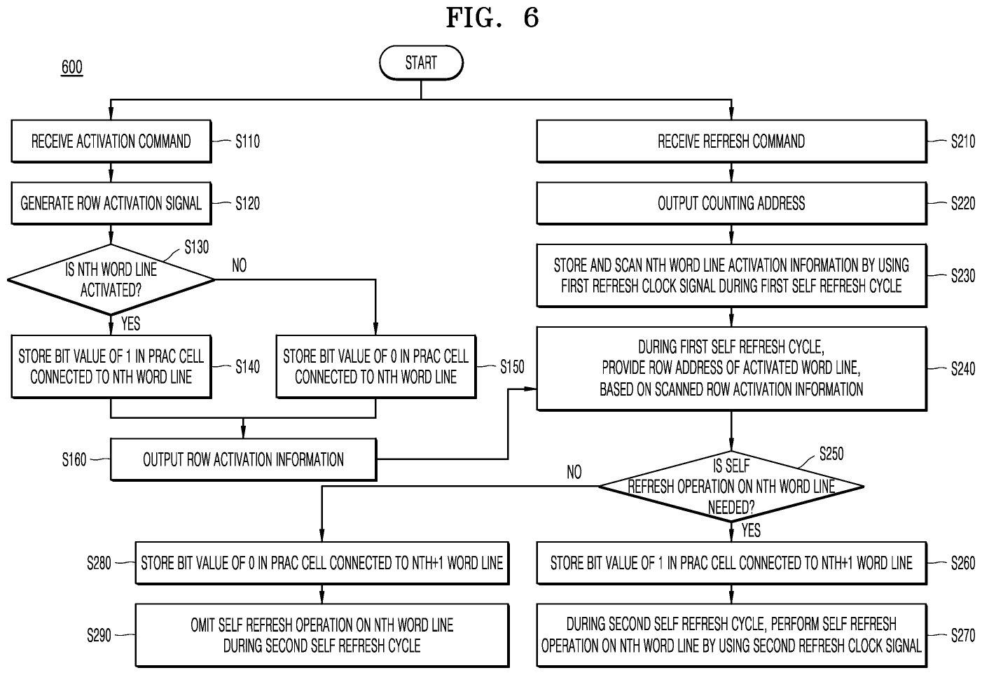

FIG. 6 is a flowchart illustrating an operating method 600 of a memory device, according to an embodiment.

Referring to FIG. 6, the activation control circuit 150 may receive the activation command ACT in operation S110. For example, the activation control circuit 150 may receive the activation command ACT output from the command decoder 120.

The activation control circuit 150 may generate the row activation signal Row_act in operation S120. For example, the row activation signal Row_act may be provided to the row decoder 160, and the row decoder 160 may activate at least one word line of the plurality of first to n-th word lines WL0 to WLn−1 corresponding to the row address R_add.

Whether the n-th word line WLn−1 is activated may be determined in operation S130.

When the n-th word line WLn−1 is activated (YES of operation S130), a bit value of one (1) may be stored at an MSB of a PRAC cell connected to the n-th word line WLn−1 in operation S140. When the n-th word line WLn−1 is not activated (NO of operation S130), a bit value of zero (0) may be stored at the MSB of the PRAC cell connected to the n-th word line WLn−1 in operation S150.

Whether the n-th word line WLn−1 is activated may be stored in the PRAC cell connected to the n-th word line WLn−1, and the sense amplifier 180 may output the row activation information Row_actinfo about the n-th word line WLn−1 in operation S160.

The refresh control circuit 130 may receive the refresh command REF in operation S210. For example, the refresh control circuit 130 may receive the refresh command REF, the self-refresh entry signal SRE, and the self-refresh exit signal SRX from the command decoder 120.

The refresh control circuit 130 may output the counting address CNT_add in operation S220. The scan circuit 141 may store and scan n-th word line activation information by using the first refresh clock signal Ref_CLKf during a first self-refresh cycle in operation S230. For example, during the first self-refresh cycle, the clock selection circuit 132 may select and output the first refresh clock signal Ref_CLKf, and the refresh counter 133 may perform a counting operation of the input address IN_add in response to the first refresh clock signal Ref_CLKf. The refresh counter 133 may output the counting address CNT_add through a counting operation of increasing a bit of the input address IN_add by one (1). The scan circuit 141 may scan and/or determine whether at least one word line of the plurality of first to n-th word lines WL0 to WLn−1 corresponding to a plurality of rows is activated, based on the row activation information Row_actinfo. For example, when the n-th word line WLn−1 is activated, the scan circuit 141 may scan a bit value of one (1) stored in the PRAC cell connected to the n-th word line WLn−1, and when the n-th word line WLn−1 is not activated, the scan circuit 141 may scan a bit value of zero (0) stored in the PRAC cell connected to the n-th word line WLn−1.

During the first self-refresh cycle, the scan circuit 141 may provide the active address ACT_add of an activated word line to the refresh determination circuit 142, based on the scanned row activation information Row_actinfo in operation S240.

During the first self-refresh cycle, whether a self-refresh operation on the n-th word line WLn−1 is needed may be determined in operation S250.

When the self-refresh operation on the n-th word line WLn−1 is needed (YES of S250), a bit value of one (1) may be stored in the PRAC cell connected to the n-th word line WLn−1 subsequent to the (n−1)-th word line WLn−2 in operation S260. During a second self-refresh cycle, a self-refresh operation on the n-th word line WLn−1 may be performed by using the second refresh clock signal REF_CLK in operation S270.

However, when a self-refresh operation on the (n−1)-th word line WLn−2 is not needed (NO of S250), namely, when a self-refresh operation may be omitted, a bit value of zero (0) may be stored in the PRAC cell connected to the n-th word line WLn−1 subsequent to the (n−1)-th word line WLn−2 in operation S280. During the second self-refresh cycle, a self-refresh operation on the n-th word line WLn−1 may be omitted in operation S290.

The memory device 100, according to an embodiment, may omit a refresh operation of a word line where an active operation is not performed, and thus, may minimize power consumption in the refresh operation, when compared to a related memory device.

In the operating method of the memory device 100, according to an embodiment, the memory device 100 may store activation information about at least one word line of the plurality of first to n-th word lines WL0 to WLn−1 corresponding to the row address R_add in the PRAC cells of the plurality of memory cells MC. A self-refresh operation on deactivated word lines may be omitted based on whether the plurality of first to n-th word lines WL0 to WLn−1 are activated, and thus, power consumption in a self-refresh operation of a memory device may be minimized, when compared to a related memory device.

FIG. 7 is a block diagram illustrating a memory device 100, according to an embodiment. The memory device 100 of FIG. 7 may include and/or may be similar in many respects to the memory device 100 described above with reference to FIG. 2, and may include additional features not mentioned above. Consequently, repeated descriptions of the memory device 100 described above with reference to FIG. 2 may be omitted for the sake of brevity.

However, referring to FIG. 7, an example where an input address IN_add<1:3> consists of a 3-bit row address R_add<1:3> for designating each of a plurality of first to eighth word lines WL0 to WL7 may be described.

Referring to FIG. 7, an address register 110 may provide a 3-bit input address IN_add<1:3> to the row address multiplexer 155. A refresh control circuit 130 may provide a 3-bit counting address CNT_add<1:3> to the mask control circuit 140 and the row address multiplexer 155. The row address multiplexer 155 may output the 3-bit row address R_add<1:3>, based on the 3-bit counting address CNT_add<1:3>, the 3-bit input address IN_add<1:3>, and a final refresh command REF_F.

A normal cell region NCR may include a plurality of normal cells (e.g., a first normal cell MC11, a second normal cell MC12, a third normal cell MC21, a fourth normal cell MC22, a fifth normal cell MC31, a sixth normal cell MC32, a seventh normal cell MC41, an eighth normal cell MC42, a ninth normal cell MC51, a tenth normal cell MC52, an eleventh normal cell MC61, a twelfth normal cell MC62, a thirteenth normal cell MC71, a fourteenth normal cell MC72, a fifteenth normal cell MC81, and a sixteenth normal cell MC82), and a PRAC cell region PCR may include a plurality of PRAC cells (e.g., a first PRAC cell MC13, a second PRAC cell MC23, a third PRAC cell MC33, a fourth PRAC cell MC43, a fifth PRAC cell MC53, a sixth PRAC cell MC63, a seventh PRAC cell MC73, and an eighth PRAC cell MC83).

For example, a case where the first word line WL0 and the third to sixth word lines WL2 to WL5 are not activated and the second word line WL1, the seventh word line WL6, and the eighth word line WL7 are activated may be described.

A bit value of zero (0) may be stored in the first PRAC cell MC13 connected to the first word line WL0 and the third to sixth PRAC cells MC33 to MC63 may be respectively connected to the third to sixth word lines WL2 to WL5. A bit value of one (1) may be stored in the second PRAC cell MC23 connected to the second word line WL1, the seventh PRAC cell MC73 may be connected to the seventh word line WL6, and the eighth PRAC cell MC83 connected to the eighth word line WL7.

It may be determined that a self-refresh operation on the second word line WL1, the seventh word line WL6, and the eighth word line WL7, which are activated word lines, may be needed, and it may be determined that a self-refresh operation on the first word line WL0 and the third to sixth word lines WL2 to WL5, which are not activated, may be omitted.

A bit value of one (1) may be stored in a PRAC cell connected to a word line subsequent to a word line which needs a self-refresh operation, and a bit value of zero (0) may be stored in a PRAC cell connected to a word line subsequent to a word line which does not need a self-refresh operation.

That is, a bit value of one (1) may be stored in the PRAC cell MC23 connected to the third word line WL2, the eighth PRAC cell MC83 connected to the eighth word line WL7, and the first PRAC cell MC13 connected to the first word line WL0, and a bit value of zero (0) may be stored in the second PRAC cell MC23 connected to the second word line WL1 and the fourth to seventh PRAC cells MC43 to MC73 respectively connected to the fourth to seventh word lines WL3 to WL6.

According to an embodiment, for example, when a self-refresh operation on the fifth word line WLA is omitted, a self-refresh operation on the sixth word line WL5 may be performed regardless of whether a self-refresh operation on the sixth word line WL6 is needed or is capable of being omitted. That is, when a self-refresh operation on an (n−1)-th word line WLn−2 is omitted, a self-refresh operation on an n-th word line WLn−1 may be performed regardless of whether a self-refresh operation on the n-th word line WLn−1 has to be performed or omitted.

For example, according to an embodiment, when the number of activated word lines is more (greater) than the number of stored active word lines of a refresh counter (e.g., refresh counter 133) and/or the number of active word lines stored in a memory device (e.g., memory device 100) as a result of scanning whether the (n−1)-th word line WLn−2 and the n-th word line WLn−1 are activated, an unconditional self-refresh operation on the (n−1)-th word line WLn−2 and the n-th word line WLn−1 may be performed.

In an embodiment, when the number of activated word lines is less than the number of stored active word lines of a refresh counter (e.g., refresh counter 133) and/or the number of active word lines stored in a memory device (e.g., memory device 100) as a result of scanning whether the (n−1)-th word line WLn−2 and the n-th word line WLn−1 are activated, a self-refresh operation on the (n−1)-th word line WLn−2 and the n-th word line WLn−1 may be omitted.

When the number of activated word lines is more (greater) than a threshold value as a result of scanning whether the (n−1)-th word line WLn−2 and the n-th word line WLn−1 are activated, an unconditional self-refresh operation on the (n−1)-th word line WLn−2 and the n-th word line WLn−1 may be performed. As another example, when the number of activated word lines is less than the threshold value as a result of scanning whether the (n−1)-th word line WLn−2 and the n-th word line WLn−1 are activated, a self-refresh operation on the (n−1)-th word line WLn−2 and the n-th word line WLn−1 may be omitted.

According to an embodiment, the memory device 100 may store activation information about the plurality of first to eighth word lines WL0 to WL7 corresponding to the row address R_add in the first to eighth PRAC cells MC13 to MC83. For example, the memory device 100 may determine whether at least one of the plurality of first to eighth word lines WL0 to WL7 corresponding to the row address R_add are activated, and based thereon, the memory device 100 may not perform a self-refresh operation on word lines corresponding to a row address which is not activated and may perform a self-refresh operation on only word lines corresponding to activated row addresses.

That is, the memory device 100 may determine whether word lines corresponding to row addresses of PRAC cells in the plurality of memory cells MC are activated, and based thereon, the memory device 100 may perform a self-refresh operation on only memory cells connected to word lines corresponding to an activated row address and may omit a self-refresh operation on memory cells connected to word lines corresponding to a deactivated row address.

Therefore, the memory device 100 may omit a refresh operation of a word line where an active operation is not performed, and thus, may minimize power consumption in the refresh operation, when compared to a related memory device.

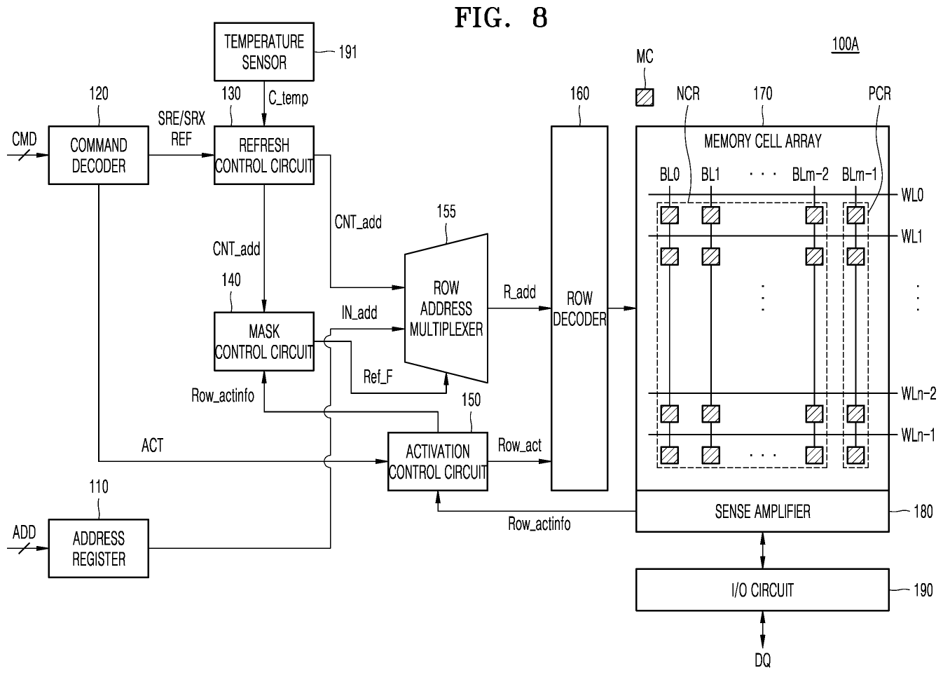

FIG. 8 is a block diagram illustrating a memory device 100A, according to an embodiment. The memory device 100A of FIG. 8 may include and/or may be similar in many respects to the memory device 100 described above with reference to FIGS. 2 and 7, and may include additional features not mentioned above. Consequently, repeated descriptions of the memory device 100A described above with reference to FIGS. 2 and 7 may be omitted for the sake of brevity.

Referring to FIG. 8, the memory device 100A may further include a temperature sensor 191.

A refresh period of the plurality of first to n-th word lines WL0 to WLn−1 included in a memory cell array 170 may be affected by a temperature, and thus, considering a driving temperature of the memory device 100A, may provide for performing a relatively more effective self-refresh operation, when compared to related memory devices.

The temperature sensor 191 may sense an internal driving temperature of the memory device 100A and may output temperature information C_Temp that may be indicative of and/or may include the internal driving temperature of the memory device 100A. In an embodiment, the temperature information C_Temp may represent whether a temperature is high or low, based on a room temperature. The temperature sensor 191 may provide the temperature information C_Temp to a refresh control circuit 130. In an embodiment, the temperature sensor 191 may use a thermal electromotive (or thermoelectric couple) sensor that may use a thermal electromotive force varying based on a temperature and a thermal conductive sensor which may sense a magnitude of a resistance varying based on a temperature. However, a temperature measurement method of the temperature sensor 191 is not limited thereto.

When the temperature information C_Temp is higher than a room temperature, the memory device 100A, according to an embodiment, may deactivate the refresh control circuit 130 to stop a self-refresh operation. Alternatively, when the temperature information C_Temp is lower than a room temperature, the memory device 100A may activate the refresh control circuit 130 to perform the self-refresh operation. However, the present disclosure is not limited in this regard.

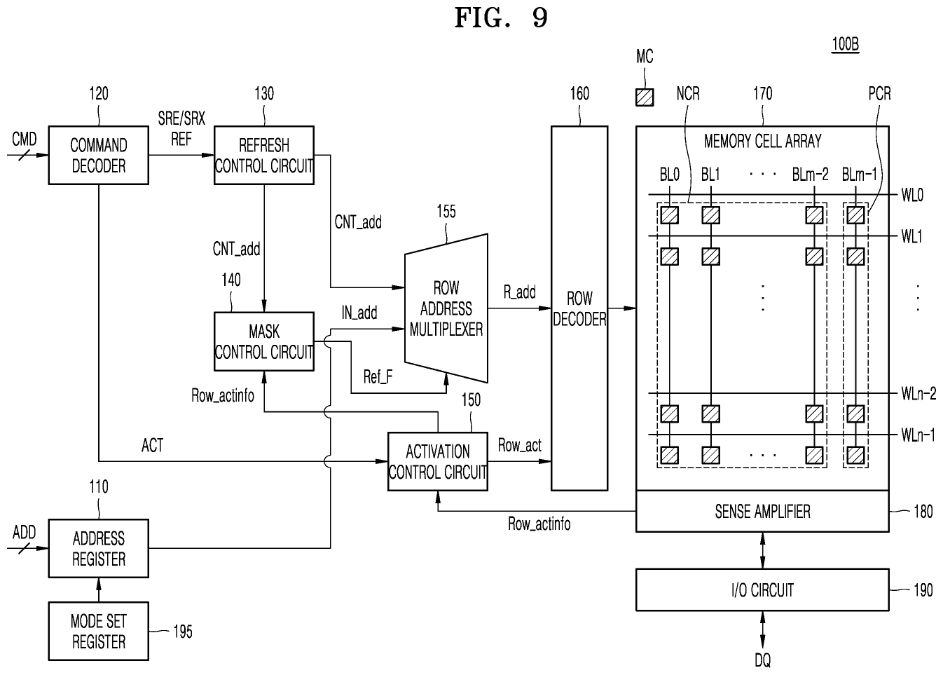

FIG. 9 is a block diagram illustrating a memory device 100B, according to an embodiment. The memory device 100B of FIG. 9 may include and/or may be similar in many respects to the memory devices 100 and 100A described above with reference to FIGS. 2, 7, and 9, and may include additional features not mentioned above. Consequently, repeated descriptions of the memory device 100B described above with reference to FIGS. 2, 7, and 9 may be omitted for the sake of brevity.

Referring to FIG. 9, the memory device 100B may further include a mode register set 195.

The mode register set 195 may be programmed for setting a plurality of operation parameters, options, various functions, characteristics, and modes of the memory device 100B. The mode register set 195 may store information used to configure an operation of the memory device 100B, so as to set an operation condition of the memory device 100B. In an embodiment, an auto refresh operation may be input to a command decoder 120 through a combination of signals generated by the mode register set 195. Accordingly, a refresh operation may be determined by command decoder 120, and an auto refresh command may be provided to the refresh control circuit 130.

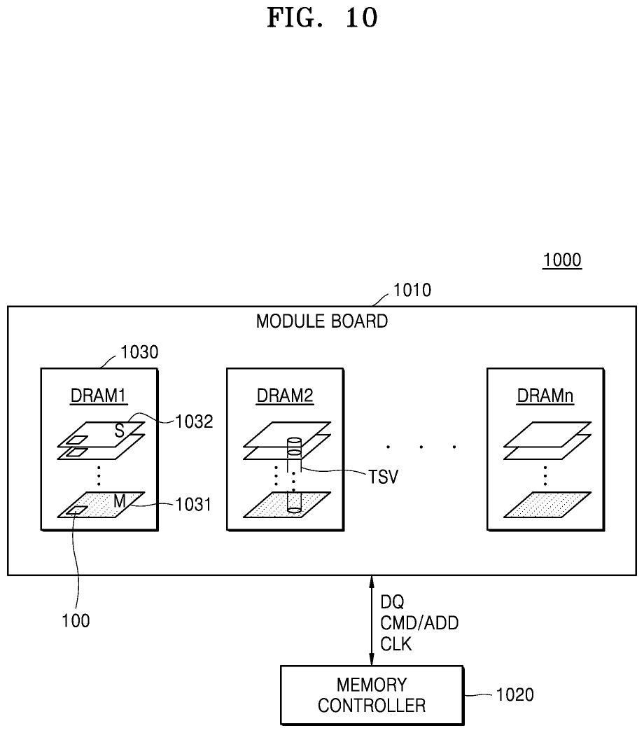

FIG. 10 is a block diagram illustrating a memory system 1000, according to an embodiment. The memory system 1000 of FIG. 10 may include and/or may be similar in many respects to the memory system 10 described above with reference to FIG. 1, and may include additional features not mentioned above. Furthermore, a memory controller 1020 and a memory device 1030 of FIG. 10 may include and/or may be similar in many respects to the memory controller 200 and the memory device 100 described above with reference to FIG. 1, respectively, and may include additional features not mentioned above. Consequently, repeated descriptions of the memory system 1000 described above with reference to FIG. 1 may be omitted for the sake of brevity.

Referring to FIG. 10, the memory system 1000 may include a memory module 1010 and the memory controller 1020.

The memory module 1010 may be equipped with one or more semiconductor memory devices 1030 mounted on a module board. The memory device 1030 may be implemented as a DRAM chip, and each of the memory devices 1030 may include a plurality of semiconductor layers. The semiconductor layers may include one or more master (M) chips 1031 and one or more slave(S) chips 1032. Signal transfer between the semiconductor layers may be performed through a through silicon via (TSV). However, the present disclosure is not limited in this regard.

The master chip 1031 and the slave chip 1032 may perform a PSR operation, according to embodiments. The master chip 1031 and the slave chip 1032 may include the memory device 100 of FIG. 1.

The memory device 1030, according to an embodiment, may store activation information about word lines corresponding to a row address in PRAC cells. For example, the memory device 1030 may determine whether the word lines corresponding to the row address are activated, and based thereon, the memory device 1030 may not perform a self-refresh operation on word lines corresponding to a row address which is not activated and may perform a self-refresh operation on only word lines corresponding to activated row addresses. That is, the memory device 1030, according to an embodiment, may omit a refresh operation of a word line where an active operation is not performed, and thus, may minimize power consumption in the refresh operation, when compared to a related memory device.

The memory module 1010 may communicate with the memory controller 1020 through a system bus. Data DQ, a command/address CMD/ADD, and/or a clock signal CLK may be transferred (transmitted) and/or received between the memory module 1010 and the memory controller 1020 through the system bus.

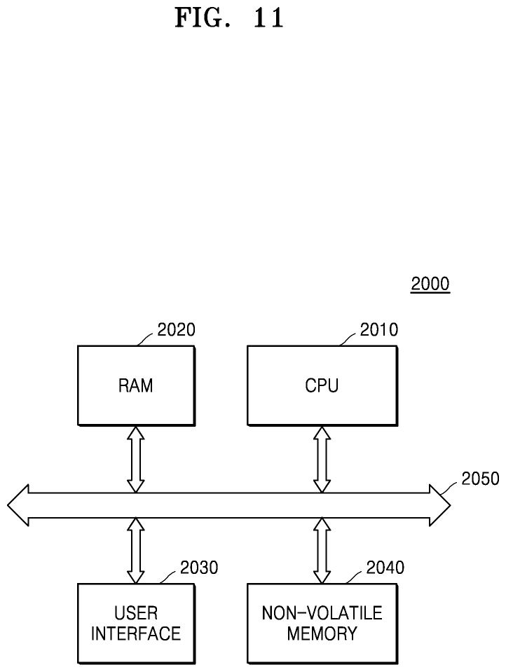

FIG. 11 is a block diagram illustrating a computing system 2000 including a memory system, according to an embodiment. The computing system 2000 may be and/or may include a smartphone, a mobile phone, a personal digital assistant (PDA), a tablet computer, a laptop computer, a personal computers (PC), a wearable device, a smart appliance, a healthcare device, an Internet of Things (IoT) device, or the like.

Referring to FIG. 11, the computing system 2000 may include a random access memory (RAM) 2020 such as, but not limited to, a semiconductor memory device. One of various embodiments described above may be applied to the semiconductor memory device equipped as the RAM 2020. For example, the RAM 2020 may be applied as the semiconductor memory device according to the embodiments, or may be applied as a memory module type. In addition, the RAM 2020 may be a concept that may include a semiconductor memory device and a memory controller.

The computing system 2000, according to an embodiment, may include a CPU 2010, the RAM 2020, a user interface 2030, and a non-volatile memory 2040, and the elements may be electrically connected to a bus 2050. The non-volatile memory 2040 may use a large-capacity storage device such as, but not limited to, a solid state disk (SSD) or a hard disk drive (HDD).

The RAM 2020 in the computing system 2000 may perform a PSR operation, according to embodiments. The RAM 2020, according to an embodiment, may store activation information about word lines corresponding to a row address in PRAC cells. For example, the RAM 2020 may determine whether the word lines corresponding to the row address are activated, and based thereon, the memory device 1030 may not perform a self-refresh operation on word lines corresponding to a row address which is not activated and may perform a self-refresh operation on only word lines corresponding to activated row addresses. That is, the RAM 2020, according to an embodiment, may omit a refresh operation of a word line where an active operation is not performed, and thus, may minimize power consumption in the refresh operation.

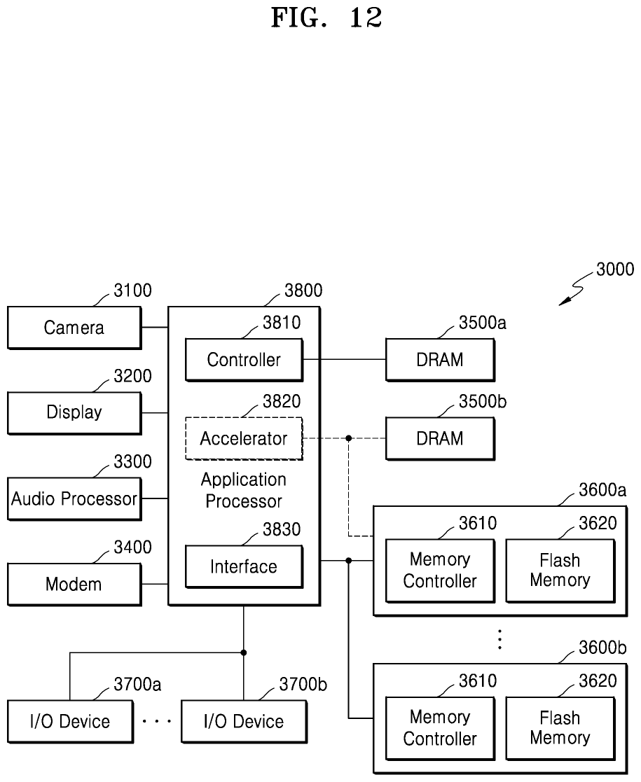

FIG. 12 is a block diagram illustrating a system 3000 for describing an electronic device including a memory device, according to an embodiment.

Referring to FIG. 12, the system 3000 may include a camera 3100, a display 3200, an audio processor 3300, a modem 3400, a plurality of DRAMs (e.g., a first DRAM 3500a and a second DRAM 3500b), a plurality of flash memories (e.g., a first flash memory 3600a and a second flash memory 3600b), a plurality of I/O devices (e.g., a first I/O device 3700a and a second I/O device 3700b), and an application processor (AP) 3800. The system 3000 may be and/or may include, but not be limited to, a laptop computer, a mobile phone, a smartphone, a PDA, a tablet computer, a personal computer (PC), a wearable device, a smart appliance, a healthcare device, an IoT device, or the like. In addition, the system 3000 may be implemented as a server or a PC.

The camera 3100 may capture a still image and/or a moving image, based on control by a user, and may store captured image/video data and/or may transmit the image/video data to the display 3200. The audio processor 3300 may process audio data included in content of a network or the first and second flash memories 3600a and 3600b. The modem 3400 may modulate and transmit and/or receive a signal so as to transmit and/or receive wired and/or wireless data, and a receiving side may demodulate a modulated signal into an original signal for recovery. The first and second I/O devices 3700a and 3700b may include devices that may provide a digital input and/or an output function, such as, but not limited to, a universal serial bus (USB) or storage, a digital camera, a secure digital (SD) card, a digital versatile disc (DVD), a network adaptor, a touch screen, or the like.

The AP 3800 may control an overall operation of the system 3000. The AP 3800 may include a control block (e.g., controller) 3810, an accelerator block or an accelerator chip 3820, and an interface block 3830. The AP 3800 may control the display 3200 so that a portion of content stored in the first and second flash memories 3600a and 3600b may be displayed by the display 3200. When a user input is received through the first and second I/O devices 3700a and 3700b, the AP 3800 may perform a control operation corresponding to the user input. The AP 3800 may include an accelerator block that may be a dedicated circuit for performing artificial intelligence (AI) data operations, and/or may include the accelerator chip 3820 separately from the AP 3800. The second DRAM 3500b may be additionally equipped in the accelerator block or the accelerator chip 3820. An accelerator may be and/or may include a functional block that may perform a certain function of the AP 3800 and may include a GPU for performing graphics data processing, a neural processing unit (NPU) for performing AI calculation and inference, and/or a data processing unit (DPU) for transmitting data.

The system 300 may include the plurality of first and second DRAMs 3500a and 3500b. The AP 3800 may control the first and second DRAMs 3500a and 3500b through command and mode register (MRS) settings that may be suitable for a Joint Electron Device Engineering Council (JEDEC) standard. Alternatively or additionally, the AP 3800 may use a DRAM interface standard to perform communication with the first and second DRAMs 3500a and 3500b, which may include the use of a cyclic redundancy check (CRC)/error correction code (ECC) function and/or a company unique function such as, but not limited to, low voltage/high speed/reliability. For example, the AP 3800 may communicate with the first DRAM 3500a through an interface suitable for JEDEC standard such as, but not limited to, Low Power Double Data Rate 4 (LPDDR4) or Low Power Double Data Rate 5 (LPDDR5), and the accelerator block or the accelerator chip 3820 may use a DRAM interface standard to perform communication so as to control the second DRAM 3500b for an accelerator having a bandwidth that may be higher than that of the first DRAM 3500a.

Although FIG. 12 illustrates the first and second DRAMs 3500a and 3500b, the present disclosure is not limited thereto and the system 300 may use an arbitrary memory such as, but not limited to, phase change random access memory (PRAM), static random access memory (SRAM), magneto-resistive random access memory (MRAM), resistive random access memory (RRAM), ferroelectric RAM (FRAM), or hybrid RAM, which may satisfy bandwidth, reaction speed, and voltage conditions and/or design constraints of the AP 3800 or the accelerator chip 3820. The first and second DRAMs 3500a and 3500b may have a latency and a bandwidth, which may be relatively less than those of the first and second I/O devices 3700a and 3700b and/or the first and second flash memories 3600a and 3600b. The first and second DRAMs 3500a and 3500b may be initialized at a power-on time of the system 3000 and may be used as a temporary storage, into which an operating system and application data may be loaded, for the operating system and the application data, and/or may be used as an execution space for various software codes.

A vector operation and four fundamental arithmetic operations such as, but not limited to, addition/subtraction/multiplication/division, an address operation, or a fast Fourier transform (FFT) operation may be performed in the first and second DRAMs 3500a and 3500b. In addition, a function used in inference may be performed in the first and second DRAMs 3500a and 3500b. As used herein, inference may be performed in a deep learning algorithm using artificial neural network, for example. The deep learning algorithm may include a training operation of training a model through various data and an inference operation of recognizing data through the trained model. In an embodiment, an image captured by the camera 3100 of a user may be signal-processed and may be stored in the second DRAM 3500b, and the accelerator block or the accelerator chip 3820 may perform an AI data operation of recognizing data by using data stored in the second DRAM 3500b and a function used in inference.

The system 3000 may include a plurality of storages and or a plurality of the first and second flash memories 3600a and 3600b each having a capacity that may be greater than that of the first and second DRAMs 3500a and 3500b. The accelerator block or the accelerator chip 3820 may perform the training operation and the AI data operation by using the first and second flash memories 3600a and 3600b. In an embodiment, the first flash memory 3600a may include a memory controller 3610a and a flash memory device 3620a, and the second flash memory 3600b may include a memory controller 3610b and a flash memory device 3620b, and a training operation and an inference AI data operation each performed by the AP 3800 and/or the accelerator chip 3820 may be more efficiently performed by using an arithmetic logic unit (ALU) included in the memory controllers 3610a and 3610b. The first and second flash memories 3600a and 3600b may store a photograph captured by the camera 3100, or may store data received through a data network. For example, the first and second flash memories 3600a and 3600b may store augmented reality/virtual reality, high definition (HD), ultra-high definition (UHD) content, or the like.

In the system 3000, the first and second DRAMs 3500a and 3500b may perform an operating method of the memory device described above with reference to FIGS. 1 to 11. The memory device, according to an embodiment, may store activation information about word lines corresponding to a row address in memory cells. For example, the memory device may determine whether the word lines corresponding to the row address are activated, and based thereon, the memory device may not perform a self-refresh operation on word lines corresponding to a row address which is not activated and may perform a self-refresh operation on only word lines corresponding to activated row addresses.

That is, the memory device, according to an embodiment, may omit a refresh operation of a word line where an active operation is not performed, and thus, may minimize power consumption in the refresh operation, when compared to a related memory device.

Hereinabove, exemplary embodiments have been described in the drawings and the specification. Embodiments have been described by using the terms described herein, but this has been merely used for describing the present disclosure and has not been used for limiting a meaning or limiting the scope of the present disclosure defined in the following claims. Therefore, it may be understood by those of ordinary skill in the art that various modifications and other equivalent embodiments may be implemented from the present disclosure. Accordingly, the spirit and scope of the present disclosure may be defined based on the spirit and scope of the following claims.

While the present disclosure has been particularly shown and described with reference to embodiments thereof, it is to be understood that various changes in form and details may be made therein without departing from the spirit and scope of the following claims.

What is claimed is:

1. A memory device, comprising:
a memory cell array comprising normal cells and per row activation count (PRAC) cells coupled with a plurality of word lines corresponding to a plurality of rows;
a refresh control circuit configured to refresh the plurality of word lines corresponding to the plurality of rows based on a refresh command; and
an activation generating circuit configured to generate a row activation signal based on an activation command,
wherein the row activation signal is configured to activate the plurality of word lines corresponding to a row address of the plurality of rows,
wherein each of the PRAC cells is configured to store row activation information, and
wherein each of the normal cells is configured to store data.

2. The memory device of claim 1, wherein each PRAC cell of the PRAC cells is further configured to:
store a bit value of one (1), based on at least one of the plurality of word lines coupled with the PRAC cell being activated; and
store a bit value of zero (0), based on the at least one of the plurality of word lines coupled with the PRAC cell not being activated.

3. The memory device of claim 1, wherein the refresh control circuit comprises:
an oscillator configured to generate, based on a self-refresh entry signal, a first refresh clock and a second refresh clock;
a clock selection circuit configured to select at least one of the first refresh clock or the second refresh clock; and
a refresh counter configured to output a counting address indicating rows which are to be refreshed in the memory cell array.

4. The memory device of claim 3, wherein a frequency of the first refresh clock is equal to a frequency obtained by multiplying a frequency of the second refresh clock by a factor, and
wherein the factor is a real number.

5. The memory device of claim 1, further comprising:
a mask control circuit configured to:
scan whether at least one of the plurality of word lines are activated; and
determine to selectively perform a refresh operation on the at least one of the plurality of word lines, based on whether the at least one of the plurality of word lines are activated.

6. The memory device of claim 5, wherein the mask control circuit comprises:
a scan circuit configured to:
receive the row activation information;
scan whether the at least one of the plurality of word lines corresponding to the plurality of rows is activated; and
output row addresses on which a refresh operation is to be performed; and
a refresh determination circuit configured to:
store refresh information in each of the PRAC cells coupled with the plurality of word lines and cause the refresh operation to be performed on the output row addresses.

7. The memory device of claim 6, wherein the refresh determination circuit is further configured to:
store the refresh information in subsequent PRAC cells of the PRAC cells coupled with the plurality of word lines corresponding to a subsequent row address.

8. The memory device of claim 6, wherein the refresh determination circuit is further configured to:
store a bit value of one (1) in each of PRAC cells coupled with subsequent word lines, based on a determination that the refresh operation is needed on the plurality of word lines; and
store a bit value of zero (0) in each of the PRAC cells coupled with the subsequent word lines, based on a determination that the refresh operation is not needed on the plurality of word lines.

9. The memory device of claim 5, further comprising:
a temperature sensor configured to:
sense a driving temperature of the memory cell array; and
provide, to the refresh control circuit, temperature information comprising the driving temperature,
wherein the refresh control circuit is further configured to control a refresh operation, based on the temperature information.

10. A memory device, comprising:
a row decoder configured to activate an n-th row corresponding to an n-th row address and an (n+1)-th row corresponding to an (n+1)-th row address, n being a positive integer greater than zero (0);
a memory cell array comprising an n-th per row activation count (PRAC) cell and n-th normal cells coupled with an n-th word line corresponding to the n-th row and an (n+1)-th PRAC cell and (n+1)-th normal cells coupled with an (n+1)-thword line corresponding to the (n+1)-th row;
an activation generating circuit configured to generate a row activation signal based on an activation command;
a mask control circuit configured to:
scan whether at least one of the n-th word line or the (n+1)-th word line is activated; and
determine to selectively perform a refresh operation on the at least one of the n-th word line or the (n+1)-th word line that is activated; and
a refresh control circuit configured to perform, based on a refresh command, the refresh operation on at least one of the n-th word line or the (n+1)-th word line,
wherein row activation information is stored in at least one PRAC cell coupled with the at least one of the n-th word line or the (n+1)-th word line that is activated.

11. The memory device of claim 10, wherein the n-th PRAC cell is configured to:
store a bit value of one (1), based on the n-th word line being activated; and
store a bit value of zero (0), based on the n-th word line not being activated, and
wherein the (n+1)-th PRAC cell is configured to:
store a bit value of one (1), based on the (n+1)-th word line being activated; and
store a bit value of zero (0), based on the (n+1)-th word line not being activated.

12. The memory device of claim 10, wherein the refresh control circuit comprises:
an oscillator configured to generate, based on a self-refresh entry signal, a first refresh clock and a second refresh clock;
a clock selection circuit configured to select at least one of the first refresh clock or the second refresh clock; and
a refresh counter configured to output a counting address indicating word lines which are to be refreshed in the memory cell array and corresponding to the word lines.

13. The memory device of claim 12, wherein a frequency of the first refresh clock is equal to a frequency obtained by multiplying a frequency of the second refresh clock by n, and
wherein n is a real number.

14. The memory device of claim 10, wherein the mask control circuit comprises:
a scan circuit configured to:
receive the row activation information;
scan whether at least one of the n-th word line or the (n+1)-th word line is activated; and
output a row address of the at least one of the n-th word line or the (n+1)-th word line that is activated; and
a refresh determination circuit configured to:
store refresh information in a PRAC cell coupled with a word line subsequent to the at least one of the n-th word line or the (n+1)-th word line that is activated, and cause a refresh operation to be performed on the row address.

15. The memory device of claim 14, wherein the refresh determination circuit is further configured to:
store a bit value of one (1) in the (n+1)-th PRAC cell coupled with the (n+1)-th word line, based on an n-th refresh operation being performed on the n-th word line;
store a bit value of zero (0) the (n+1)-th PRAC cell coupled with the (n+1)-th word line, based on the n-th refresh operation on the n-th word line being omitted;
store a bit value of one (1) in an (n+2)-th PRAC cell coupled with an (n+2)-th word line, based on an (n+1)-th refresh operation being performed on the (n+1)-th word line; and
store a bit value of zero (0) in the (n+2)-th PRAC cell coupled with the (n+2)-th word line, based on the (n+1)-th refresh operation on the (n+1)-th word line being omitted.

16. The memory device of claim 14, wherein the refresh determination circuit is further configured to:
store the refresh information in a subsequent PRAC cell coupled with a word line subsequent to a word line on which a refresh operation is performed.

17. The memory device of claim 14, wherein the refresh determination circuit is further configured to:
scan whether at least one of the n-th word line or the (n+1)-th word line is activated to obtain a number of activated word lines; and
omit performing of a refresh operation based on the number of activated word lines being more than a predetermined number.

18. The memory device of claim 10, further comprising:
a temperature sensor configured to:
sense a driving temperature of the n-th PRAC cell and the (n+1)-th PRAC cell; and
provide, to the refresh control circuit, temperature information comprising the driving temperature,
wherein the refresh control circuit is further configured to control a refresh operation, based on the temperature information.

19. An operating method of a memory device, the operating method comprising:
receiving an activation command;
generating a row activation signal;
activating, based on the row activation signal, an n-th word line corresponding to an n-th row and stopping activation of an (n+1)-th word line corresponding to an (n+1)-th row, where n is a positive integer greater than zero (0);
storing a bit value of one (1) in an n-th per row activation count PRAC cell coupled with the n-th word line;
storing a bit value of zero (0) in an (n+1)-th PRAC cell coupled with the (n+1)-th word line; and
storing a bit value of zero (0) in an (n+2)-th PRAC cell coupled with an (n+2)-th word line.

20. The operating method of claim 19, further comprising:
performing an n-th refresh operation on the n-th word line; and
omitting performing of an (n+1)-th refresh operation on the (n+1)-th word line.
